(19) United States
(12) Patent Application Publication
(10) Pub. No.: US 2004/0072423 A1
(43) Pub. Date: Apr. 15, 2004

(54) Methods and systems for electro-or electroless-plating of metal in high-aspect ratio features

(76) Inventors: Jacob Jorne, Rochester, NY (US); Judith E. Love, Rochester, NY (US); Anh Man Tran, Wilsonville, OR (US)

Correspondence Address: Edwin V Merkel, Nixon Peabody, Clinton Square, PO Box 31051, Rochester, NY, 14603, US

(21) Appl. No.: 10/466,222

(22) PCT Filed: Jan. 14, 2002
(86) PCT No.: PCT/US02/00851

(30) Foreign Application Priority Data
Jan. 12, 2001 (US) 60261537

(51) Int. Cl. C25D 3/38; H01L 21/44

(52) U.S. Cl. 438/687; 205/291

(57) ABSTRACT

Methods of electrodeposition and electroless deposition are disclosed which afford super-filling of high-aspect ratio features on wafers by exposing wafers and electrolytic solutions in which they are immersed to conditions effective to induce reduction of metal ions in the electrolytic solution, preferably by a multiple step reduction, whereby electrodeposition of metal occurs at a bottom of each of the features until the features are substantially super-filled. Systems for performing such methods are described as are the resulting wafers produced thereby.

The application claims the benefit of U.S. Provisional Patent Application Serial No. 60/261,537, filed Jan. 12, 2001, which is hereby incorporated by reference in its entirety.

### FIELD OF THE INVENTION

The present invention relates to generally a method and system for electro- or electroless-plating of metal in high-aspect ratio features on wafers, as well as the resulting wafers produced thereby.

### BACKGROUND OF THE INVENTION

Electroplating is the leading technology for copper metallization of sub-quarter micron interconnects, because it allows the filling of trenches and vias without pinch-off and voids and because it is capable of giving uniform copper thickness over the wafers, as required for the subsequent chemical-mechanical polishing (Jorne, “Uniformity of copper electroplating of wafers”, Abs. 256, 193^{rd} Electrochem. Soc. Meeting, San Diego, Calif., May 3-8 (1998); Jorne, “Macro-Throwing Power and Micro-Filling Power in Copper Electroplating of Wafers,” Abs. 726, 196^{th} Meeting of the Electrochem. Soc., Hawaii, (1999)).

Some conventional copper electroplating processes use additives in the electroplating bath to achieve electrodeposition of the copper with a smooth or level top surface. For example, these conventional processes may be used in printed circuit board fabrication to achieve copper deposits of uniform thickness across the surface of the circuit board, to level or increase the smoothness of the copper deposit, and to increase the rate at which copper deposits inside holes and vias in the circuit board (relative to the surface). Use of these additives allows consistent electrical and mechanical properties of the copper to be achieved across the circuit board's surface. These conventional processes typically perform the copper electrodeposition from acid sulfate solutions with certain organic additives (Jorne, “Macro-Throwing Power and Micro-Filling Power in Copper Electroplating of Wafers,” Abs. 726, 196^{th} Meeting of the Electrochem. Soc., Hawaii, (1999)). A number of organic additives are commercially available. These organic additives help achieve the level top surface by increasing the deposition rate of the copper at the lower points of the deposition surface relative to the upper points on the deposition surface. It is believed that the mechanism for this leveling effect is that (a) the organic additives tend to absorb onto the plating surface, thus inhibiting the deposition of copper at the point of absorption, and (b) the mass transfer rate of the organic additives tends to be greater for higher points on the plating surface compared to the lower points on the plating surface. Consequently, the deposition rate at the lower points on the plating surface tends to be greater than the deposition rate at the higher points on the surface. This difference in deposition rate helps to achieve deposition with a level top surface.

It has previously been reported, however, that these conventional organic additives are only marginally effective when the plating surface contains very small (i.e., sub-micron) features with high aspect ratios (see U.S. Pat. No. 6,284,121 to Reid). In particular, the copper fill in a small feature tends to have voids or seams. These voids or seams may increase the resistance of the conductive path intended to be formed by the copper deposited in the feature or, even worse, create an open circuit. This problem becomes critical in applying copper electrodeposition processes in integrated circuit fabrication. For example, contact and via holes in an integrated circuit can be a quarter micron or less in width, with an aspect ratio of four-to-one or greater. In particular, voids in the contacts and vias may result in high resistance interconnects or even open-circuits.

In addition to these problems, the monitoring and control of additives in the electrolyte are difficult tasks (Y. Dori & P. Hey, Semicond. Fabtech, 11, 271 (2000)). Monitoring is required, because these organic additives are consumable during the plating process and, therefore, must be replenished. For these reasons, it would be desirable to identify a process which can achieve super-filling of high-aspect ratio trenches or vias using an electrolyte solution which is substantially devoid of such organic or polymeric additives.

The present invention is directed to overcoming these deficiencies in the art.

### SUMMARY OF THE INVENTION

A first aspect of the present invention relates to a method of electroplating a wafer which includes: introducing a wafer, having a substantially flat surface and high-aspect ratio features each with an opening in the flat surface, at least partially into a electrolytic solution including metal ions, ligands, and metal ion-ligand complexes; and exposing the wafer and electrolytic solution to an electrical current under conditions effective to reduce the metal ions within the features, whereby electrodeposition of metal occurs at a bottom of each of the features until the features are substantially super-filled.

A second aspect of the present invention relates to a system which includes: a first chamber containing a first electrolytic solution including metal ions, ligands, and metal ion-ligand complexes; a wafer holder adapted to receive a wafer such that the wafer is immersed at least partially in the first electrolytic solution of the first chamber; and an anode immersed at least partially in the first electrolytic solution of the first chamber; wherein upon connection of the system to a power supply, an electrical current flows through the anode, the first electrolytic solution, and the wafer, as a cathode, under conditions effective to reduce the metal ions during electrodeposition of metal onto the wafer.

A third aspect of the present invention relates to a method of electroless deposition of metal onto a wafer which includes: introducing a wafer, having a substantially flat surface and high-aspect ratio features each with an opening in the flat surface, at least partially into an electrolytic solution including metal ions, ligands, and metal ion-ligand complexes; and exposing the wafer and the electrolytic solution to a metal sheet in sufficient proximity and electrically connected to the wafer, under conditions effective to reduce the metal ions, whereby deposition of metal occurs at a bottom of each of the features until the features are substantially super-filled. According to one embodiment the metal sheet is distinct of the wafer, whereas in a second embodiment the metal sheet is coated onto the flat surface of the wafer (i.e., as a seed layer).

A fourth aspect of the present invention relates to a system which includes: a first chamber containing a first electrolytic solution including metal ions, ligands, and metal ion-ligand complexes; a wafer holder adapted to receive a wafer such that the wafer is immersed at least partially in the first electrolytic solution of the first chamber; and a metal sheet located in sufficient proximity and electrically connected to the wafer, upon introduction of the wafer into the wafer holder, which metal sheet induces reduction of the metal ions during deposition of metal onto the wafer. According to one embodiment the metal sheet is distinct of the wafer, whereas in a second embodiment the metal sheet is coated onto the flat surface of the wafer.

A fifth aspect of the present invention relates to a wafer including a metal interconnect which is prepared according to a process of the present invention.

A sixth aspect of the present invention relates to a wafer which includes a substrate including a plurality of features formed therein and a metal interconnect which substantially super-fills the plurality of features formed in the substrate, wherein the metal interconnect is formed of a polycrystalline metal including a substantially unidirectional crystal orientation.

The present invention offers a number of advantages for depositing metals inside sub-micron features and cavities of wafers, where the features and cavities are characterized by a high aspect ratio. Such features, including trenches, vias, and holes, are filled from the bottom up to achieve super-filling without voids or seams. This process is particularly relevant to copper metalization of on-chip interconnects. The process of the present invention allows for the preparation of wafers using electrolytic solutions which are substantially devoid of conventional organic additives (e.g., leveling agents). By eliminating the need for these leveling agents, the monitoring and control of their concentration in the electrolytic solution can be avoided, affording significant cost savings. An additional benefit of the process of the present invention is the ability to eliminate, or at least minimize, the need for subsequent chemical-mechanical polishing of the substrate by anodic removal of the excess metal and electropolishing of the substrate.

### BRIEF DESCRIPTION OF THE DRAWINGS

FIG. 1 illustrates the characteristics of features formed in the flat surface on a wafer, where the feature has a height (h), a width (a), and aspect ratio (h/a), and a distance between the flat surface and a location within the feature (x). Three types of filled features are shown: those filled with a void, with a seam, or super-filled (or bottom-up filled).

FIG. 2 is a graph illustrating copper distribution in uncomplexed electrolyte (with pinch-off and void formation) versus copper distribution in complexed electrolyte (with super-filling or bottom-up electrodeposition). The Thiele parameters are Φ₁²=², Φ₂²=1, and Φ₂²=5 where (x) is the normalized distance from the surface of the wafer.

FIG. 3 is a graph illustrating the relationship between filling power and the three Thiele parameters, Φ₁²=1, Φ₂² and Φ₂²=5. Super-filling occurs when the filling power is greater than 1. Filling power is the ratio between the deposition rate at the bottom of the trench verses the deposition rate at the wafer's flat surface.

FIG. 4 is a flow chart indicating various steps according to one embodiment of the electroplating method of the present invention.

FIG. 5 is a schematic diagram illustrating the various components of an electroplating system according to one embodiment of the present invention.

FIG. 6 is a flow chart indicating various steps according to one embodiment of an electroless deposition of the present invention.

FIG. 7 is a schematic diagram illustrating the various components of an electroless deposition system according to one embodiment of the present invention. In FIG. 7A, the metal sheet is distinct of the wafer, whereas in FIG. 7B it is plated onto the wafer.

FIGS. 8A-B are images of scanning electron micrographs illustrating copper bottom-up or super-filling of vias from additive-free electrolyte. Magnification is 30,000× (8A) and 10,000× (8B).

FIG. 9 is a graph illustrating the X-ray diffraction pattern of a super-filled feature. Thee diffraction pattern reveals columnar growth of copper with almost exclusively (1,1,1) orientation.

### DETAILED DESCRIPTION OF THE INVENTION

The present invention relates to processes and systems for plating metal onto semiconductor wafers. Prior to plating, the wafers are prepared with a thin barrier layer and, typically, an electrically conductive seed layer on top of the barrier layer. These procedures can be carried out according to any suitable process for applying the barrier and seed layers, including chemical vapor deposition, sputtering, physical vapor deposition, etc. The surface of the wafer also includes a number of features, such as trenches, vias, various size holes, cavities, recesses, etc. It is these features which are filled according to the processes of the present invention, thereby forming conductive metal interconnects on the wafer.

According to one aspect of the present invention, a method of electroplating a wafer is provided. This method is carried out by introducing a wafer, having a substantially flat surface and high-aspect ratio features each with an opening in the flat surface, at least partially into an electrolytic solution which includes metal ions, ligands, and metal ion-ligand complexes; and exposing the wafer and electrolytic solution to an electrical current under conditions effective to induce a reduction of the metal ions, preferably a multiple step reduction of the metal ions, whereby electrodeposition of metal occurs at a bottom of each of the features until the features are substantially super-filled. In performing this method of the present invention, it is preferable that substantially all of the features (i.e., in contact with the electrolytic solution) become super-filled with the metal.

According to a related aspect of the present invention, a method of electroless plating metal onto a wafer is provided. This method is carried out by introducing a wafer, having a substantially flat surface and high-aspect ratio features each with an opening in the flat surface, at least partially into an electrolytic solution including metal ions, ligands, and metal ion-ligand complexes; and exposing the wafer and the electrolytic solution to a metal sheet in sufficient proximity and electrically connected to the wafer, under conditions effective to induce a reduction of the metal ions, preferably a multiple step reduction of the metal ions, whereby deposition of metal occurs at a bottom of each of the features until the features are substantially super-filled. In performing this method of the present invention, it is preferable that substantially all of the features (i.e., in contact with the electrolytic solution) become super-filled with the metal. As noted hereinafter, the metal sheet can be pre-deposited onto the flat surface of the wafer or the metal sheet can be distinct of the wafer.

As used herein, the term “high-aspect ratio” is a characteristic of the features on the wafer and refers to the ratio of the height (h):width (a) of the feature. A high-aspect ratio is an aspect ratio which is about 4 or higher, preferably about 5 or higher. As the width of submicron features becomes smaller, allowing a greater number of features to be formed on a wafer surface, the aspect ratio will also likely increase. Typically, the high-aspect ratio features on today's wafers will have a width of about 0.2 to about 0.3 microns. The process of the present invention is particularly useful for filling such high-aspect ratio features, although it is not limited to such use.

As used herein, the term “multiple step reduction” refers to the process of reducing a metal ion in solution into its metal state (i.e., deposited), where the process involves an intermediate state which is stabilized by the presence in solution of a complexing agent or ligand. This multiple step reduction favors the bottom-up or super-filling of features due to the equilibrium and kinetics which occur inside and outside of the features between the metal ion-ligand complex and the metal ion, ligand, or metal. The equilibrium and kinetics are discussed in greater detail below.

As used herein, the term “electroless” refers to the absence of an electrical current. During electroless deposition, the local galvanic action, caused by the difference in potential between the bottom of the feature and the surface of the wafer, favors deposition of the metal at the bottom of the trench.

The electrolytic solution which is used for metal deposition includes metal ions, ligands, and metal ion-ligand complexes preferably, though not exclusively, in an aqueous solution. Notably, the electrolytic solutions as used with the present invention are substantially devoid of organic additives of the type which are employed in many conventional metal deposition procedures to enhance the likelihood bottom-up filling.

The concentration of metal ions in the electrolytic solution is preferably between about 0.01 to about 2 M, more preferably between about 0.1 to about 1 M. Suitable metals which can be deposited in accordance with the present invention include, without limitation, copper, silver, gold, platinum, nickel, lead, palladium, tin, or alloys thereof. Thus, metal ions which exist within the electrolytic solution include, without limitation, copper ions, silver ions, gold ions, platinum ions, nickel ions, lead ions, palladium ions, tin ions and combinations thereof. The electrolytic solution is typically formed upon the addition of metal salts to water or aqueous solutions. When copper is employed, suitable copper sources generally include copper salts, but more particularly, without limitation, copper sulfate, copper nitrate, copper perchlorate, copper alkyl sulfonate, copper halide, and combinations thereof.

The concentration of ligand in the electrolytic solution is preferably between about 0.001 to about 0.1 M, more preferably between about 0.01 to about 0.1 M. Suitable ligands are compounds or ions which are capable of stabilizing the intermediate state of the multiple step reduction from metal ion to metal state. Exemplary ligands include, without limitation, halide (e.g., chloride, bromide, or iodide) ions, acetonitrile, cyanide ions, ammonia, thiosulfate, thiocyanate, sulfuric acid, nitric acid, EDTA (ethylenediamine tetraacetic acid), and combinations thereof. Where the ligand itself is ionic in the electrolytic solution, the ligand can be provided by introducing into solution a ligand source. Exemplary ligand sources include, e.g., HX acid where X is a halide ion and R—CN where R is sulfur or an alkali metal. Other ligand sources can also be used as long as they supply the desired ligand in solution.

Preferred electrolytic solutions include about 0.2 M copper sulfate (CuSO₄) as a source of copper ions for deposition and either about 0.01 M halide ions or about 0.01 M acetonitrile as the ligand. These electrolytic solutions can further include sulfuric acid up to about 1.0 M.

Deposition Kinetics

Without being bound by theory, the dynamics of the equilibrium can be understood with reference to the deposition of copper in the absence of ligand or complexing agent, as well as in the presence of ligand or complexing agent. The principles of the dynamics are not, however, limited to copper or specific ligands.

It is believed that bottom-up filling of narrow and high-aspect ratio features is facilitated by complexing the cuprous ion in the electroplating solution with a complexing agent, thus shifting the electrochemical potential for copper deposition inside the cavity to a more noble value, and electrodeposition favorably occurs at the bottom of the trench. Analysis of the undesirable pinch-off formation in uncomplexed solution is discussed immediately below, followed by the bottom-up filling from solutions containing complexed cuprous ions. A description of the mechanism of self-regulating selective filling of trenches and holes is also disclosed herein.

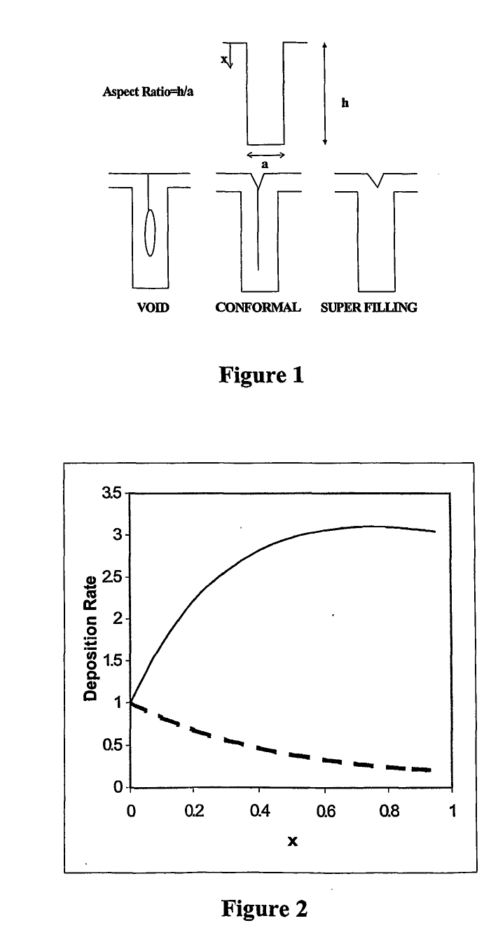

Referring to FIG. 1, in a trench having a high aspect ratio (h/a), the following electrochemical reaction occurs between the copper ion and the wall of the trench in the absence of a complexing agent:

$${Cu}^{2 +} + 2 e {->}^{{k}_{1}} Cu \qquad \{ Eq . 1 \}$$

where C²⁺ is the copper ion in solution and Cu is the deposited copper metal. The metal ion diffuses into the trench and reacts there. Defining a dimensional coordinate z=x/h, where×is the distance from the mouth of the trench, the conservation equation for Cu²⁺ in the absence of a complexing agent becomes:

d² [Cu²⁺]/dz²−Φ₁² [Cu²⁺]=0 {Eq. 2}

where the Thiele modulus is defined by

Φ₁²=kh²/D₁ {Eq. 3}

and represents the ratio of the reaction kinetics to diffusion. In Equation 3, k₁ is the reaction rate and D₁ is the diffusivity of Cu²⁺. k₁ is related to the true heterogeneous rate constant k₁^{t} by:

k₁=k_{/m}^{t}(a/2) {Eq. 4}

The boundary conditions are:

z=0 [Cu²⁺]=[Cu²⁺]₀ {Eq. 5}

z=1 −d[Cu²⁺]/dz=Φ₁²/(h/a) [Cu²⁺] {Eq. 6}

where the first boundary condition (Equation 5) implies bulk concentration at the top, while the second boundary condition (Equation 6) implies that the flux to the bottom surface is equal to the rate of the electrochemical reaction there. Both conditions assume the absence of a complexing agent.

The solution for the distribution of Cu²⁺ along the depth of the trench is given by:

[Cu²⁺]/[Cu²⁺]₀=C₁ sin h Φ₁z+cos hΦ₁z {Eq. 7}

where C₁ is a constant, determined by the boundary conditions. The distribution of the electrodeposition rate is given by

R=k₁ [Cu²⁺]=k₁[Cu²⁺]₀(C₁ sin Φ₁z+cos hΦ₁z) {Eq. 8}

and is presented in FIG. 2 (dotted line). It can be seen that the electrodeposition is normally preferred at the top of the trench, resulting in undesirable pinch-off and void formation (see FIG. 1).

However, if the intermediate metal ion is complexed by a ligand, then the electrodeposition is carried out with an intermediate step:

$$\begin{matrix}{Cu}^{2 +} + e {->}^{{k}_{1}} {Cu}^{+} & \{ Eq . 9 \} \\ {Cu}^{+} + e {->}^{{k}_{2}} Cu & \{ Eq . 10 \}\end{matrix}$$

where Cu²⁺ is now the uncomplexed metal ion, Cu⁺ is an intermediate species (i.e., the complexed ion) and Cu is the electrodeposited copper metal.

The conservation equations for species Cu²⁺ and Cu⁺ are:

d² [Cu²⁺]/dz²−Φ₁² [Cu²⁺]=0 {Eq. 11}

d²[Cu⁺]/dz²−Φ₂² [Cu⁺]+Φ₁₂²[Cu²⁺]=0 {Eq. 12}

where Φ₂ and Φ₂₂ are the Thiele modulus for Cu²⁺ and Cu⁺, respectively, and (D₁₂₂ is a mixed Thiele modulus defined by

Φ₁₂²=k₁h²/D₂ {Eq. 13}

which represents the ratio between the kinetics of the first reaction and the diffusion of Cu⁺.

The boundary conditions at z=0 imply bulk concentrations there. The boundary conditions at z=1 imply that the reaction rates of Cu²⁺ and Cu⁺ are equal to their respective diffusion fluxes there:

z=0 [u²⁺]=[Cu²⁺]₀ {Eq. 14}

[Cu⁺]=[Cu⁺]₀ {Eq. 15}

z=1−d[Cu²⁺]/dz=Φ₁²(h/a)[Cu²⁺] {Eq. 16}

z=1−d[Cu⁺]/dz=Φ₂²/(h/a) [Cu⁺] {Eq. 17}

The analytical solution is given by:

[Cu²⁺]/[Cu²⁺]₀=C₁ sin h φ₁z+.cos hΦ₁z {Eq. 18}

[Cu⁺]/[Cu⁺]₀=C₃ sin h φ₂z+C₄ cos h Φ₂z+C₅ sin h φ₁z+C₆ cos h φ₁z {Eq. 19}

where C₁, C₃, C₄ and C₆ are constants, determined by the boundary conditions and are functions of the three Thiele parameters Φ₁, Φ₂, and Φ₁₂ and the aspect ratio h/a.

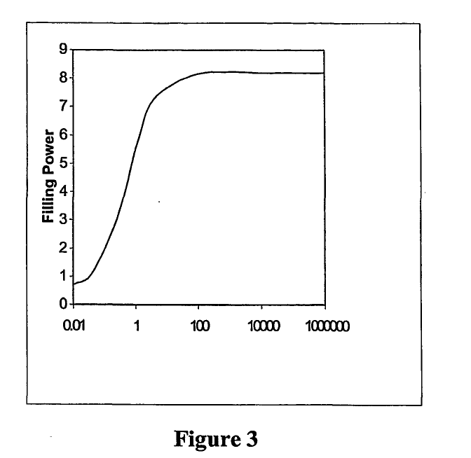

The rate of electrodeposition along the depth of the trench is given by R=k₂[Cu⁺] and is presented in FIG. 3, where it is being compared as well to the case of no intermediate reduction, for various Thiele parameters Φ₁², Φ₂² and Φ₁₂². For particular sets of Thiele parameters, the rate of copper electrodeposition is higher at the bottom of the trench and super-filling is expected.

In the case of preferential filling of features from the bottom up, the current distribution should be highly non-uniform: high at the bottom of the feature and low at the wafer's flat surface. Thus, the feature filling power FP is defined here as the ratio between the deposition rate at the bottom of the trench and at the wafer's flat surface (i.e., at the top of the trench):

FP=R_{b}/Rₜ {Eq. 20}

where R_{b} and Rₜ are the rates of electrodeposition at the bottom of the trench, z=1, and at the top flat area, z=0, respectively. This can also be expressed as the ratio of the corresponding current densities at the bottom and the top:

FP=i_{b}/iₜ {Eq. 21}

The filling power is plotted in FIG. 3 for various ratios of the Thiele modulus Φ₁, Φ₂₂ and Φ₁₂². As can be seen, for particular set of Thiele modulus, the filling power is greater than 1, and super filling of the feature occurs.

The filling power represents the ratio of the copper thickness at the bottom to that at the top, and in order to achieve highly non-uniform filling, i.e., super-filling, the filling power should be significantly larger than one, preferably about twice as great as the aspect ratio (i.e., greater than about 8). Undesirable pinch-off and void formation occur when the filling power is smaller than one. Uniform conformity occurs when the filling power is equal to one, however such filling is also undesirable as it results in the formation of seams and voids.

From the above descriptions, therefore, it should be understood that (1) the addition of a ligand to the electrolytic solution of copper ions results in rapid cuprous ion complexation in the bulk solution; and (2) within features of the wafer the ligand is rapidly depleted (when the concentration of the ligand is much smaller than the concentration of the metal ions) affording a mostly uncomplexed solution, whereas the solution in the bulk, over the flat surface, is complexed. The complexation shifts the electrochemical potential to a more electro-negative value in comparison to the uncomplexed solution inside the cavities. Therefore, either upon passing a cathodic current or upon inducing a local current, deposition is achieved inside the cavities and bottom-up filling occurs. Furthermore, the filling-up is self-regulatory because as the neck of the cavity becomes smaller, the depletion of the complexant is more significant and the shift in potential is larger, resulting in self-regulation of the filling process and the avoidance of pinch-off at the top of the cavity.

Electrodeposition

In the case of copper electrodeposition, the reduction occurs in two steps:

Reduction of cupric to cuprous:

Cu²⁺+e=Cu⁺ {Eq. 22}

E⁰=+0.153 V vs. SHE

Reduction of cuprous to copper:

Cu⁺+e=Cu {Eq. 23}

E⁰=+0.520 V

where E⁰ is the equilibrium standard potential. The cuprous ion is very unstable in typical copper solution, such as CuSO₄. In contact with metallic copper, the following equilibrium is established:

Cu+Cu²⁺=2Cu⁺ {Eq. 24}

K₁=[Cu⁺]²[Cu²⁺]=1.86×10⁻⁶

This means that the equilibrium is strongly shifted to the left and cuprous ion is practically absent. However, if ligand of the type described above is added to the solution, then complexation of the cuprous ion occurs:

Cu⁺+nA^{z}=Cu(A)ₙ^{1+nz} {Eq. 25}

K₂=[Cu(A)ₙ^{1+nz}]/[Cu⁺][A^{z}]ⁿ {Eq. 26}

where A is the ligand and z is its charge. The overall equilibrium reaction is then:

Cu+Cu²⁺nA=2Cu(A)ₙ^{1+nz} {Eq. 27}

K₃=K₂²/K₁ {Eq. 28}

Therefore, cuprous ions are stabilized when K₂>K₁. Under such conditions, copper metal will be oxidized to cuprous ion and etching occurs. For chloride ligand, by way of example, the following equilibrium constants are available:

Cu+Cu²⁺+2C₁−=2CuCl K₃=6.28×10⁷

Cu+Cu²⁺+4C₁−=2CuCl₂ K₃=1.86×10⁵

Cu+Cu⁺+6C₁−=2CuCl₃²⁻ K₃=2.336×10⁴

If the copper substrate, upon which copper electrodeposition takes place, has narrow features, then the solution inside the cavity etches the copper and, since the diffusion of the complexing agent into the cavity is slow, equilibrium is attained inside the cavity. Further diffusion and drift of cupric ions results in cupric-dominant solution inside the cavity, while outside the cavity the solution contains the complexed cuprous ion. Consequently, the electrochemical potential outside the trench is shifted to a more negative value in comparison to the flat surface, and copper is favorably deposited at the bottom of the trench.

Not only does complexation of cuprous ion in solution induce deposition inside the features, but etching occurs simultaneously on the flat surface of the wafer. Unlike the inside of the features where deposition occurs as described above, the external surface is exposed to a continual renewal of the ligand, thereby stabilizing the cuprous ion outside the feature. As a result, deposition is inhibited outside the feature. For example, chloride ion forms complexes with cuprous ion, thus stabilizing its existence in solution. The standard potential for copper electrodeposition from complexed cuprous ion solution is shifted to a more negative value. When a trenched surface is exposed, for example, to a solution of CuSO₄ and HCl, the confined volume inside the trenches is depleted of chloride ion, and therefore the dominant process there is the reduction of cupric ion (Cu₂₄) to copper. At the external flat surface, chloride ion is available and cuprous chloride complexes are formed, from which the deposition of copper is more difficult. A self-regulating mechanism is established: as the neck of the feature tends to close up, chloride ion is prevented from diffusing into the confined volume, and consequently there is a depletion of chloride ion there and the dominant mechanism inside the trench is the reduction of copper from its cupric ion state. Even if the top is completely blocked by the deposited metal, a bi-polar mechanism can be established in which metal is concurrently deposited on the outside pinch-off metal layer and dissolved at the inside side of the pinch-off metal layer, and further deposited inside the cavity.

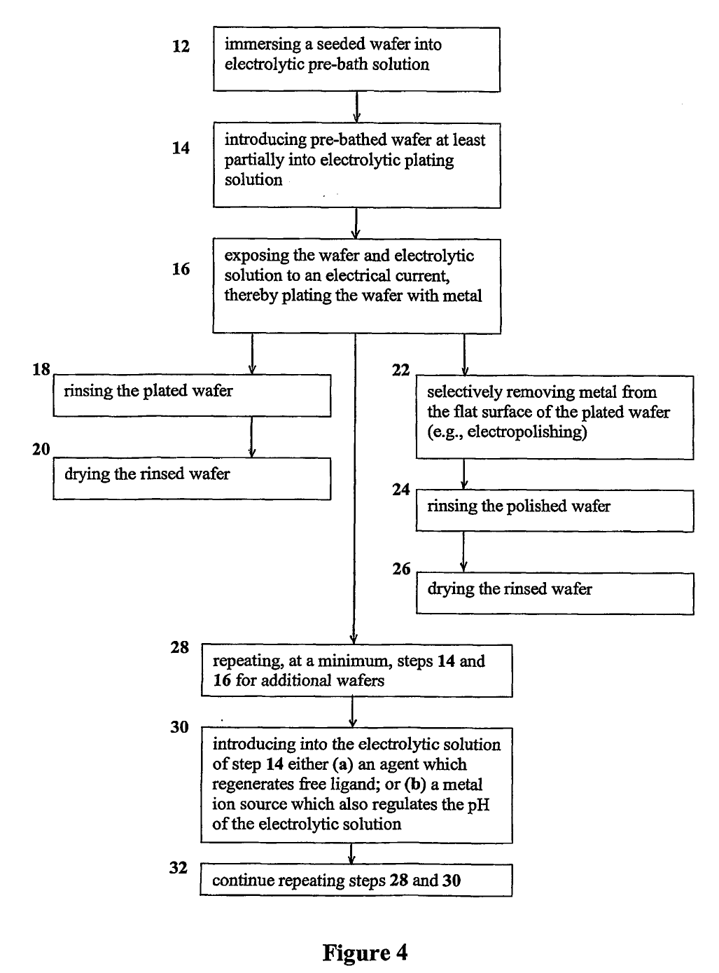

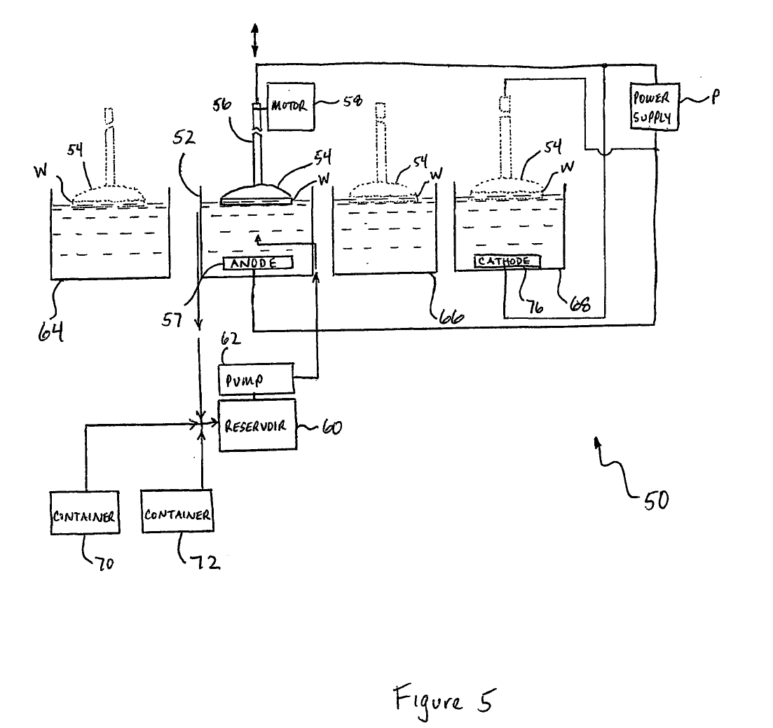

Accordingly, an electroplating process according to one embodiment of the present invention can be carried out as illustrated in FIG. 4.

Specifically, a pre-seeded wafer is immersed in a pre-bath electrolytic solution at step 12. This pre-bath electrolytic solution can be of the same type which is subsequently used for electroplating or this solution can include only metal ions in the absence of any ligand. Although not required, the pre-bath is often performed for filling the features with electrolytic solution, removing gas bubbles, etc.

Thereafter, at step 14, the pre-bathed wafer is transferred into a chamber or cell which includes an electrolytic solution used for electroplating. The wafer is introduced at least partially into the electrolytic solution, preferably such that only the surface on which metal is to be deposited is in contact therewith. This solution includes metal ions (i.e., of the metal or metals to be plated), ligand, and metal ion-ligand complexes. After introduction to the electroplating cell, at step 16 both the wafer and electrolytic solution are exposed to an electrical current under conditions effective to induce a multiple step reduction of the metal ions (as described above). Suitable electrical currents are from about 1 to about 100 mA/cm, preferably about 10 to about 50 mA/cm. Basically, this is achieved using a system as disclosed hereinafter, whereby both a wafer (as a cathode) and an anode, also in the electrolytic solution, are electrically coupled to a power supply. Following a sufficient dwell time, which is usually about 1 to about 10 minutes, preferably about 2 to about 5 minutes, the electrical current passing through the anode, electrolytic solution, and wafer is halted. Variations of the dwell time are, of course, possible where lesser or greater quantities of metal are deposited.

During the deposition process, i.e., at which time electrical current passes through the anode, electrolytic solution, and wafer, the wafer is preferably rotated at about 10 or more revolutions per minute, preferably about 20 to about 200 or more preferably about 50 to about 100 revolutions per minute. Rotation of the wafer is desirable to allow gas bubbles to be removed (i.e., allowing deposition to occur), as well as enhancing electrolyte transport to the wafer which, in turn, improves the uniformity of the electroplated layer. Further, the thickness profile of the electroplated layer can readily be adjusted by changing the rotational speed of the assembly.

In addition, it may also be desirable to circulate the electrolytic solution toward the wafer (whether it is rotating or not). The electrolytic solution can be pumped into the chamber or cell such that the flow of introduced electrolytic solution is applied directly against and centrally of the wafer surface which is exposed thereto. This ensures that the surface of the wafer is continuously being exposed to a bulk solution under conditions where metal ions are substantially fully complexed by available ligand.

Typically, this process produces wafers with a sufficiently smooth coated surface, in which case the plated wafer can be rinsed and dried at steps 18 and 20, respectively. Drying can be carried out by rotating the wafer at substantially higher revolutions per minute, e.g., 500 or more revolutions per minute.

Where polishing is desired, however, such polishing can be performed by selectively removing metal from the flat surface between the openings of the features at step 22. Any suitable polishing procedure can be employed. For example, using the same electrolytic solution during depositing, a reverse current can be passed through the wafer (now anode), electrolytic solution, and cathode under conditions effective anodically to remove metal which remains on the flat surface between the openings of features. Alternatively, the wafer can be introduced into an electropolishing solution of the type known in the art (e.g., an electropolishing solution having a viscosity greater than about 10 centipoise, such as a 1 M phosphoric acid solution) and then exposed to a reverse current as described above. Regardless of the approach used for selective removal of the metal from the flat surface, the current utilized can be about 1 to about 1000 mA/cm.

The above process is intended to be repeated with additional wafers (step 28). However, depending on the type of anode used in the electrolytic deposition procedure, either the concentration of metal ions or the concentration of free ligand will be depleted to some extent.

In particular, when the anode is formed of the same type of metal which is being deposited into the features of the wafer during deposition, then it is desirable to introduce into the electrolytic solution an agent which regenerates free ligand (step 30,a). The agent which regenerates free ligand is preferably ammonia or an oxidant, such as oxygen, air, or nitric acid. Other known oxidants can also be employed.

In contrast, when the anode is formed of an inert metal, then it is desirable to introduce into the electrolytic solution a metal ion source which regulates the pH of the electrolytic solution (step 30,b). Metal hydroxides or metal oxides are typically employed. For example, when using an electrolytic solution for deposition of copper with an inert anode, exemplary copper ion sources which also regulate the pH of the electrolytic solution include, without limitation, Cu(OH)₂, CuO, or CuCO₃. Replenishment of copper ions when an inert anode is employed is disclosed in U.S. Pat. No. 5,997,712 to Ting et al., which is hereby incorporated by reference in its entirety.

Regardless of the type of anode utilized, and thus the type of agent which is used to replenish or regenerate the electrolyte components of the electrolytic solution, the introduction of these agents can be carried out continuously or periodically. If periodically, once such agents are introduced, then the process can be repeated for additional wafers until such later time that further introduction of such agents is needed, as so on.

An apparatus (or, when including the various solutions, a system) for performing such electroplating can be of conventional design, but including the electrolytic solutions and supplies or reservoirs of the agents which are introduced into the electrolytic solutions to replenish or regenerate the electrolyte or ligand components thereof. Exemplary apparatus for carrying out electroplating procedures of the type described above are disclosed in U.S. Pat. No. 6,099,702 to Reid et al. and U.S. Pat. No. 6,139,712 to Patton et al., each of which is hereby incorporated by reference in its entirety.

An apparatus 50 (or system) in accordance with one embodiment of the present invention is shown in FIG. 5. The apparatus includes a first chamber or cell 52 containing a first electrolytic solution including metal ions, ligands, and metal ion-ligand complexes; a wafer holder 54 adapted to receive a wafer W such that the wafer is immersed at least partially in the first electrolytic solution of the first chamber; and an anode 56 immersed at least partially in the first electrolytic solution of the first chamber; wherein upon connection of the apparatus to a power supply P, an electrical current flows through the anode, the first electrolytic solution, and the wafer, as a cathode, under conditions effective induce a multiple step reduction of the metal ions during electrodeposition of metal onto the wafer.

The wafer holder 54 can be a clamshell of the type known in the art, which can be mounted on a rotatable spindle 56 driven by a motor 58 under a computerized control system. As is also known in the art, the wafer holder can be adjustable between a number of positions, allowing the wafer to be immersed in solutions or removed therefrom and transferred to different solutions in multiple chambers.

The first electrolytic (or plating) solution is continually provided to the first chamber or cell 52 by a pump 62. Generally, the plating solution flows upwards, through an inlet, to the center of wafer W and then radially outward and across the wafer. The plating solution then overflows the first chamber or cell (outlet) to an overflow reservoir 60 (as indicated by arrows), where it can be filtered and returned to pump 62. If desired, the inlet, the outlet, or both, can be positioned in a manner which imparts circulation of the first electrolytic solution within the first chamber.

A DC power supply P has a negative output lead electrically connected to wafer W through one or more slip rings, brushes and contacts. The positive output lead of power supply P is electrically connected to an anode 57. During use, power supply P biases wafer W to have a negative potential relative to anode 57, causing an electrical current to flow from anode 57 to wafer W (as cathode). As used herein, electrical current flows in the same direction as the net positive ion flux and opposite the net electron flux. This causes electrochemical reactions of the type described above on wafer W, which results in the super-filling deposition of the metal within the features on wafer.

The entire wafer holder 54 is vertically adjustable to allow movement of the wafer W into the plating solution. Moreover, the wafer holder can optionally be adjusted relative to one or more chambers or cells to facilitate additional treatment of the wafer, either before or after the electrodeposition.

For instance, prior to electrodeposition, it may be desirable to soak the wafer in a pre-bath. The pre-bath electrolytic solution may be contained in the second chamber 64, with the pre-bath electrolytic solution also containing metal ions of the type to be plated onto the wafer. When the second chamber is employed, the wafer holder is adjustable between a first position where a wafer received therein is at least partially immersed in the plating electrolytic solution of the first chamber or cell 52 and a second position where the wafer is at least partially immersed in the pre-bath electrolytic solution of the second chamber or cell 64.

Moreover, it may be desirable to rinse the wafer immediately following the electroplating process. The rinsing can be carried out in a third chamber or cell 66 containing either a third electrolytic solution, deionized water or an alcohol, but preferably deionized water or alcohol. When the third chamber is employed, the wafer holder is adjustable between a first position where a wafer received therein is at least partially immersed in the plating electrolytic solution of the first chamber or cell 52, a second position where the wafer is at least partially immersed in the pre-bath electrolytic solution of the second chamber or cell 64, and/or a third position where the wafer is at least partially immersed in the third electrolytic solution, deionized water, or alcohol of the third chamber or cell 66.

Finally, as noted above, in certain instances it may be desirable to perform polishing of the plated wafer selectively to remove metal from the flat surface of the wafer. In those circumstances, a fourth chamber or cell 68 can optionally be provided (i.e., containing an electropolishing solution). When the fourth chamber is employed, the wafer holder is adjustable between a first position where a wafer received therein is at least partially immersed in the plating electrolytic solution of the first chamber or cell 52, a second position where the wafer is at least partially immersed in the pre-bath electrolytic solution of the second chamber or cell 64, a third position where the wafer is at least partially immersed in the third electrolytic solution, deionized water, or alcohol of the third chamber or cell 66, and/or a fourth position where the wafer is at least partially immersed in the electropolishing solution of the fourth chamber or cell 68. The electroplating solution can be of the type described above. This fourth chamber or cell 68 also includes a cathode immersed at least partially in the electropolishing solution and connected to the power supply P, whereby reversal of the current flow through the electrical connection of the wafer W, causing the wafer to act as anode, anodically removes metal on a surface of the wafer in contact with the electropolishing solution.

As noted above, depending upon the type of anode employed in the first chamber or cell 52, it may be desirable to introduce into the electrolytic solutions one or more agents which replenish or regenerate the electrolyte or ligand components thereof. Thus, where the anode is formed of the same metal which is electrodeposited onto the wafer, a container 70 is provided which includes the agent which regenerates free ligand. Similarly, where the anode is formed of an inert metal, a container 72 is provided which includes the metal ion source which regulates the pH of the plating electrolytic solution. Both containers 70 and 72 are in fluid communication with the first chamber or cell 52 anywhere throughout the circulation path of the plating electrolytic solution (e.g., reservoir).

Electroless Deposition

Furthermore, it is also possible to deposit copper inside the confined trenches and holes without passing an external current. This can be achieved by simultaneous electrodeposition of copper from its uncomplexed state inside the confined volume, while copper dissolution occurs simultaneously on the flat surface where the complexed cuprous ion is stabilized by the availability of a complexing ligand. Deposition occurs inside the confined trench:

Cu₂₊+2e=Cu {Eq. 29}

E⁰=+0.34 V vs. SHE

while dissolution occurs at the flat surface:

Cu+Cl⁻=CuCl+e {Eq. 30}

E₀=−0.08 V vs. SHE

The electrons consumed during deposition inside the trenches are supplied by the dissolution of copper at the flat surface, thus a mixed potential is established between the two regions.

When cupric salt solution (e.g., CuSO₄) is brought in contact with copper metal, the following equilibrium is established:

Cu+Cu²⁺=2Cu⁺ {Eq. 31}

and its equilibrium constant is:

K₁=[Cu⁺]²/[Cu²⁺]=1.86×10⁻⁶ at 25° C.

This reaction is highly shifted to the left and will not occur when copper metal is immersed in cupric salt solution. However, if chloride or any other ligand is added to the solution, then the following complexation reaction occurs:

Cu⁺+n Cl⁻=Cu(Cl)ₙ¹⁻ⁿ {Eq. 32}

K₂=[Cu(Cl)ₙ]¹⁻ⁿ/[Cu⁺][Cl⁻]ₙ {Eq. 33}

where K₂>>1 if the complexation is strong.

When the concentration of chloride is sufficiently high, equilibrium is shifted to the right and etching of copper occurs. If the concentration of chloride is non-uniform over the surface of the copper substrate, then non-uniform deposition and even etching can occur simultaneously. When submicron trenches and holes exist on the copper substrate, the diffusion of chloride into the confined volumes is limited and consequently, the chloride concentration there is quickly depleted. The flat surface of the copper substrate is sufficiently exposed to high chloride concentration; therefore, etching may occur there. In contrast, inside the trenches and holes, cupric ion is present and deposition of copper occurs there, resulting in super-filling of the features. The wafer is maintained under mixed potential, where the cathodic current at the features is equal to the anodic current at the flat surface. The net result is the transfer of copper from the flat surface into the trenches until complete filling is obtained. Under this mechanism, a sufficient amount of copper must be pre-deposited on the flat surface or provided in the form of a metal sheet electrically connected to the wafer and in sufficient proximity in order to be transferred into the holes and trenches.

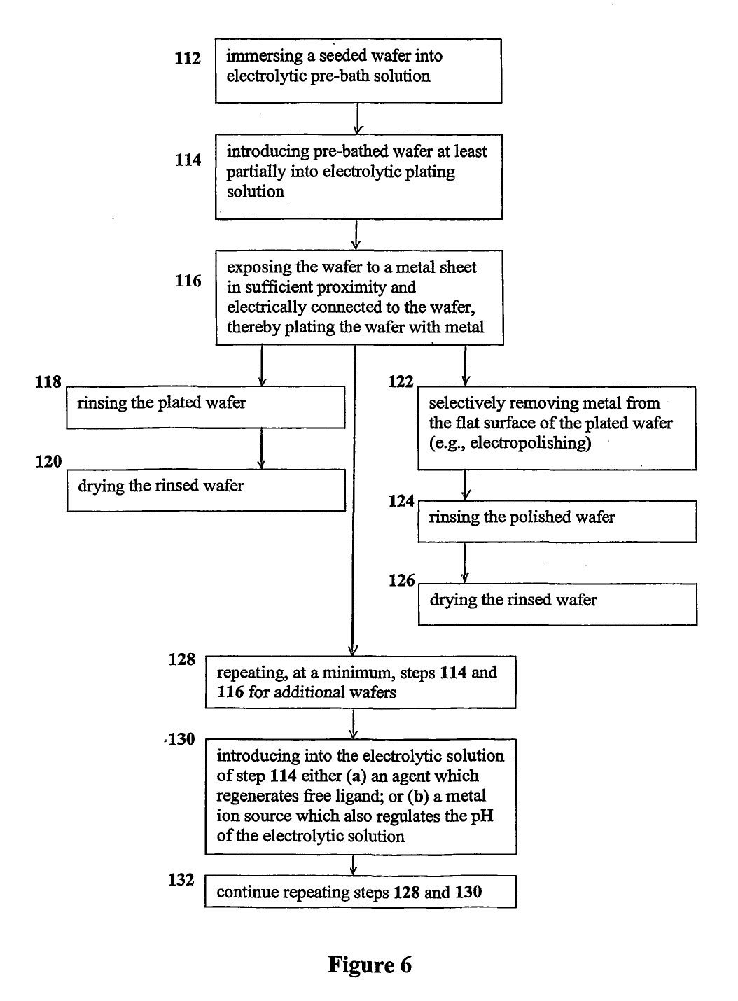

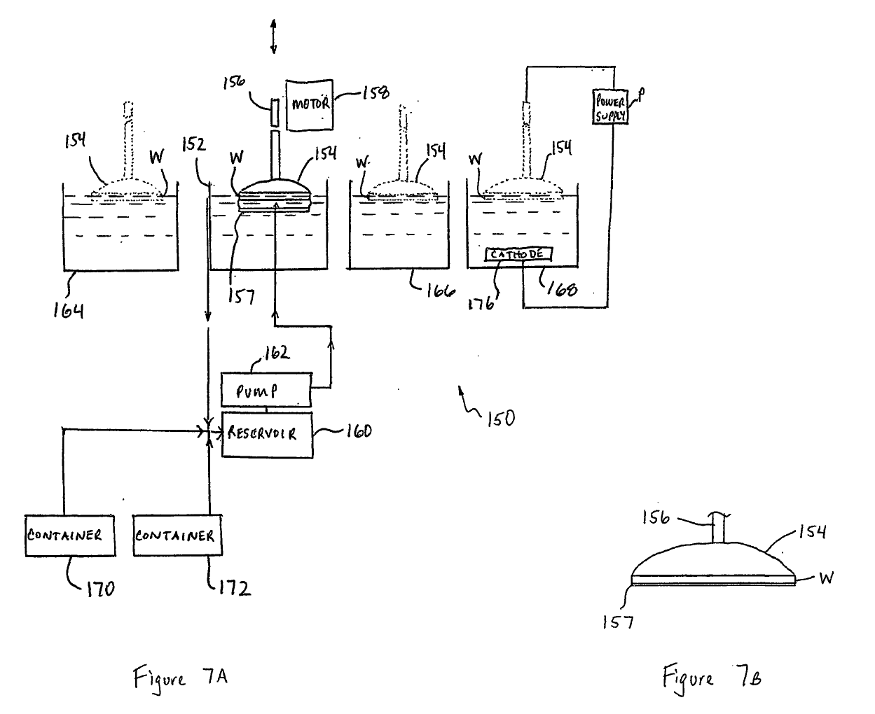

Accordingly, an electroless deposition process according to one embodiment of the present invention can be carried out as illustrated in FIG. 6.

Specifically, a seeded wafer is immersed in a pre-bath electrolytic solution at step 112, which is substantially identical to step 12 described above for electrodeposition.

Thereafter, at step 114, the pre-bathed wafer is transferred into a chamber or cell which includes an electrolytic solution used for electroless deposition. The wafer is introduced at least partially into the electrolytic solution, preferably such that only the surface on which metal is to be deposited is in contact therewith. This solution includes metal ions (i.e., of the metal or metals to be plated), ligand, and metal ion-ligand complexes. Thereafter, at step 116 a metal sheet and the wafer are exposed to one another by bringing them into sufficient proximity with one another and are electrically connected, under conditions effective to induce a multiple step reduction of the metal ions (as described above). Basically, this is achieved using a system as disclosed hereinafter. Following a sufficient dwell time, which is usually about 0.5 to about 10 minutes, preferably about 1 to about 5 minutes, the deposition process is halted.

During the deposition process, the wafer is preferably rotated as described above. In addition, it may also be desirable to circulate the electrolytic solution toward the wafer as described above.

Typically, this process produces wafers with a sufficiently smooth coated surface, in which case the plated wafer can be rinsed and dried at steps 118 and 120, respectively. Drying can be effected by rotating the wafer at substantially higher revolutions per minute, e.g., 500 or more revolutions per minute.

Where polishing is desired, however, such polishing can be performed by selectively removing metal from the flat surface between the openings of the features at step 122. Any suitable polishing procedure can be employed, including the procedures described above for anodically removing metal.

The above process is intended to be repeated with additional wafers (step 28). However, during the repeated deposition processes, either the concentration of metal ions or the concentration of free ligand will be depleted to some extent. As a result, it may be desirable to introduce into the electrolytic solution an agent which regenerates free ligand (step 130,a) or a metal ion source which also regulates the pH of the electrolytic solution (step 130,b), both substantially as described above with respect to the electrodeposition embodiment. Once the concentration of the electrolytic solution components has been replenished, the entire process can be repeated. Replenishment of the electrolytic solution components can be continuous or periodic.

An apparatus 150 (or system) in accordance with one embodiment of the present invention is shown in FIG. 7A. The apparatus includes a first chamber or cell 152 containing a first electrolytic solution including metal ions, ligands, and metal ion-ligand complexes; a wafer holder 154 adapted to receive a wafer W such that the wafer is immersed at least partially in the first electrolytic solution of the first chamber; and a metal sheet 156 located in sufficient proximity and electrically connected to the wafer, upon introduction of the wafer into the wafer holder, which metal sheet induces a multiple step reduction of the metal ions during deposition of metal onto the wafer. As shown in FIG. 7A, the metal sheet is distinct of the wafer, and electrically connected to the wafer by electrically conductive clips or the like. Preferably, the metal sheet is positioned such that it is between about 0.1 to about 1 cm from the wafer. As shown in FIG. 7B, the metal sheet can also be pre-deposited onto the flat surface of the wafer itself in the form of a metal seed layer, in which case the galvanic action of the deposition procedure etches metal from the flat surface and deposits the metal within the features. Both of these approaches can also be employed in combination.

The wafer holder 154, spindle 156, and motor 158 are substantially as described above with respect to the apparatus for electrodeposition in FIG. 5. Also as described above, the entire wafer holder 154 is vertically adjustable to allow movement of the wafer W into the plating solution. Moreover, the wafer holder can optionally be adjusted relative to one or more chambers or cells (i.e., pre-bath chamber 164; rinsing chamber 166; and/or electropolishing chamber 168) to facilitate additional treatment of the wafer, either before or after the electrodeposition.

To facilitate electropolishing, a DC power supply P has a positive output lead electrically connected to wafer W through one or more slip rings, brushes and contacts. The negative output lead of power supply P is electrically connected to a cathode 156. During use, power supply P biases cathode 156 to have a negative potential relative to wafer W, causing an electrical current to flow from wafer W to cathode 156. As used herein, electrical current flows in the same direction as the net positive ion flux and opposite the net electron flux. This causes anodic removal of metal deposited on the flat surface of the wafer W as described above.

The first electrolytic (or plating) solution is continually provided to the first chamber or cell 152 by a pump 162 substantially as described above with respect to the apparatus for electrodeposition in FIG. 5. Moreover, containers 170 and 172 are provided with the agent which regenerates free ligand and the metal ion source which also regulates the pH of the plating electrolytic solution, respectively. Both containers 170 and 172 are in fluid communication with the first chamber or cell 152 anywhere throughout the circulation path of the plating electrolytic solution (e.g., reservoir). A separate pump may be used to introduce the contents of containers 170 and 172 into the electrolytic solution.

Further aspects of the present invention relate to the wafers which includes metal interconnects and are prepared in accordance with a process of the present invention.

In particular, according to one embodiment, a wafer of the present invention is characterized by a substrate including a plurality of features formed therein (which may or may not be high-aspect ratio features) and a metal interconnect which substantially super-fills the plurality of features formed in the substrate, wherein the metal interconnect is formed of a polycrystalline metal including a substantially unidirectional crystal orientation. It was surprisingly discovered that wafers plated with copper in accordance with the present invention possessed interconnects having polycrystalline copper characterized by a substantially unidirectional crystal orientation. Specifically, the copper possessed Miller indices of almost exclusively the (1,1,1) type. It is believed that this substantially uni-directional orientation will improve conductivity of the thin layer as well as improve its resistance against electrical migration.

### EXAMPLES

The following examples are intended to illustrate, but by no means are intended to limit, the scope of the present invention as set forth in the appended claims.

### Example 1

### Electrodeposition of Copper Using Chloride Ligand

Copper was electroplated from complexed cuprous ion bath containing: 0.25M CuSO₄ and 0.1M HCl in the absence of any organic additives. Bath temperature was 25° C. The substrate was a 200 mm silicon wafer with sub-micron trenches and vias varying from 1 to 0.2 micrometer width and 1 micron depth. The wafer was first covered by a 0.05 micron barrier layer of Ta, using PVD, and then by a 0.05 micron copper seed layer by sputtering and CVD. The electroplating was conducted under an apparent current density of 10 mA/cm² for a period of 5 minutes. Complete filling of all the trenches was achieved without void formation. Reversing the current at 10 mA/cm² for a period of 3 minutes resulted in the removal of most of the excess copper from the flat surface of the substrate.

### Example 2

### Electrodeposition of Copper Using Chloride Ligand and Copper Sulfate Pre-Bath

Copper was elecroplated inside high aspect trenches and holes with sub-micron width. The wafer with the trenches and holes was initially covered with a typical 0.05 micron barrier layer (e.g. TaN) and a 0.05 micron thin seed layer of copper. Then the wafer was immersed for 5 minutes in concentrated 0.25M CuSO₄ solution and then transferred, while still wet, to a 0.2M CuSO₄ solution with 0.1M HCl. Using this technique, the trenches and holes are filled with pure CuSO₄ solution without the complexing chloride, while the external flat surface is exposed to the HCl-containing solution. Copper deposition occurs inside the trenches and holes, while copper etching occurs on the flat surface. The overall process is the transfer of the pre-deposited copper from the flat surface to inside the trenches and holes, therefore it is needed to have enough copper on the flat surface, sufficiently to be transferred into the trenches and holes. Complete filling of all the trenches was achieved without void formation.

### Example 3

### Electrodeposition of Copper to Form Substantially Exclusive (1,1,1) Crystal Orientation

A 200 mm silicon wafer is covered on one side with a thin TaN barrier layer and a thin copper seed layer. 0.30 micron trenches and vias are distributed all over the one sided wafer. The wafer was mounted facing down on a rotating wafer holder, which rotates at about 200 rpm. The wafer was immersed in an electrolyte solution containing 0.2M CuSO₄ without sulfuric acid and with 0.01M acetonitrile (CH₃CN) in water. The electrolytic solution was pumped and circulated against the wafer at a rate of about 5 gpm, with the total volume of the electrolyte being about 15 Gal. The anode employed was a ruthenized titanium screen. The applied current density was 10 mA/cm² (the total current was about 3A). Plating was conducted for 1 minutes, which corresponds to an average copper layer of about 1 micron. After the plating, the wafer was thoroughly washed with deionized water and ethyl alcohol and quickly spin-dried in air.

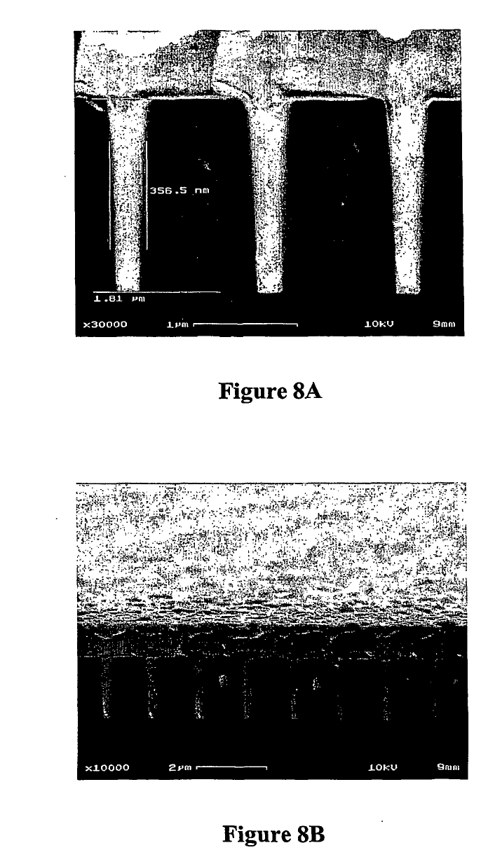

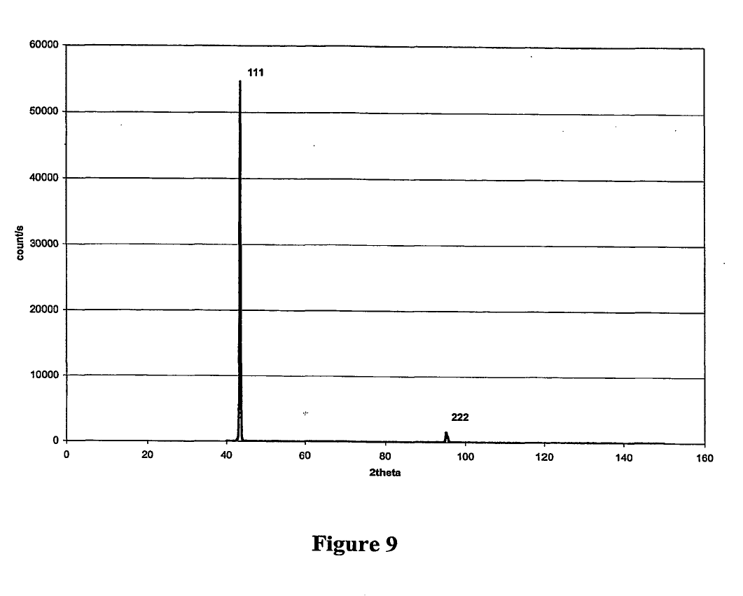

Scanning electron micrograph images are provided in FIGS. 8A-8B, which illustrate superfilling of the features, free of seams and voids. It should also be noted that the surface of the electroplated wafer is smooth. As shown in FIG. 9, X-ray diffraction analysis reveals columnar growth of copper with almost exclusively (1,1,1) orientation.

### Example 4

### Electroless Deposition of Copper Using Chloride Ligand

A 200 mm silicon wafer with submicron trenches and vias varying from 0.2 to about 1 micron in width and 1 micron depth will be covered by a 0.05 micron barrier layer of TaN using physical vapor deposition. Thereafter, a 0.1 micron seed layer will be applied to the exposed flat surface by sputtering and chemical vapor deposition. The prepared wafer will then be immersed for 5 minutes with its active side (to which the barrier layer and seed layer will have been applied) in an electrolytic solution of 0.25M CuSO₄ and 0.1M HCl in the absence of organic additives.

The complete and selective filling of the trenches and holes will be achieved without applying an external electrical current. Since chloride ion tends to complex cuprous ions, the exposure of the solution to the copper seed layer will result in the depletion of the chloride ion inside the high aspect trench or hole, thus inducing an electro-chemically favored and selective deposition inside, while copper etching will occur on the external flat surface. The charge needed for the electrodeposition inside the trench or hole will be supplied by the charge associated with the dissolution of the copper seed layer on the flat surface. This corresponds to local galvanic action deposition of copper inside the trenches and holes, while copper will be dissolving at the flat surface, thus regenerating the copper ion concentration in the bulk solution. Complete filling of all the trenches is expected without void formation.

Although the invention has been described in detail for the purpose of illustration, it is understood that such detail is solely for that purpose, and variations can be made therein by those skilled in the art without departing from the spirit and scope of the invention which is defined by the following claims.

What is claimed:

1. A method of electroplating a wafer comprising:
introducing a wafer, having a substantially flat surface and high-aspect ratio features each with an opening in the flat surface, at least partially into a electrolytic solution comprising metal ions, ligands, and metal ion-ligand complexes; and
exposing the wafer and electrolytic solution to an electrical current under conditions effective to reduce the metal ions within the features, whereby electrodeposition of metal occurs at a bottom of each of the features until the features are substantially super-filled.

2. The method according to claim 1 wherein said exposing induces a multiple step reduction of metal ions.

3. The method according to claim 1 further comprising after said exposing:
selectively removing metal from the flat surface between the openings of the features.

4. The method according to claim 1 wherein the metal is copper, silver, gold, platinum, nickel, lead, palladium, tin, or alloys thereof.

5. The method according to claim 1 wherein the ligand is selected from the group consisting of halide ions, acetonitrile, cyanide ions, ammonia, thiosulfate, thiocyanate, sulfuric, acid, nitric acid, EDTA, and combinations thereof.

6. The method according to claim 1 wherein the electrolytic solution comprises:
a copper source selected from the group consisting of copper salts, copper sulfate, copper nitrate, copper perchlorate, copper allyl sulfonate, copper halide, and combinations thereof; and
a ligand selected from the group consisting of halide ions, acetonitrile, cyanide ions, ammonia, thiosulfate, thiocyanate, sulfuric acid, nitric acid, EDTA, and combinations thereof.

7. The method according to claim 6 wherein the electrolytic solution comprises CuSO₄ and acetonitrile.

8. The method according to claim 6 wherein the electrolytic solution further comprises sulfuric acid.

9. The method according to claim 1 wherein the electrolytic solution is substantially devoid of additives.

10. The method according to claim 1 further comprising:
rotating the wafer during said exposing.

11. The method according to claim 1 further comprising:
circulating the electrolytic solution toward the wafer.

12. The method according to claim 1 wherein during said exposing, the wafer is a cathode in the electrolytic solution and an anode is present in the electrolytic solution, which anode and cathode are coupled to a power supply.

13. The method according to claim 12, wherein the anode is formed of a metal which is the same as the metal electrodeposited into the features during said exposing.

14. The method according to claim 13 further comprising:
repeating said introducing and exposing for different wafers; and
introducing into the electrolytic solution an agent which regenerates free ligand.

15. The method according to claim 14 wherein the agent which regenerates free ligand is an oxidant.

16. The method according to claim 12 wherein the anode is formed of an inert metal.

17. The method according to claim 16 further comprising:
repeating said introducing and exposing for different wafers; and
introducing into the electrolytic solution a metal ion source which also regulates the pH of the electrolytic solution.

18. The method according to claim 17 wherein the metal is copper and the metal ion source which also regulates the pH of the electrolytic solution is Cu(OH)₂, CuO, or CuCO₃.

19. A wafer comprising a metal interconnect which is prepared according to the process of claim 1.

20. A wafer comprising:
a substrate including a plurality of features formed therein and
a metal interconnect which substantially super-fills the plurality of features formed in the substrate, wherein the metal interconnect is formed of a polycrystalline metal comprising a substantially unidirectional crystal orientation.

21. The wafer according to claim 20, wherein the polycrystalline metal is copper.

22. The wafer according to claim 21, wherein the copper possesses (1,1,1) Miller indices.

23. A system comprising:
a first chamber containing a first electrolytic solution comprising metal ions, ligands, and metal ion-ligand complexes;
a wafer holder adapted to receive a wafer such that the wafer is immersed at least partially in the first electrolytic solution of the first chamber; and
an anode immersed at least partially in the first electrolytic solution of the first chamber; wherein upon connection of the system to a power supply, an electrical current flows through the anode, the first electrolytic solution, and the wafer, as a cathode, under conditions effective to reduce the metal ions during electrodeposition of metal onto the wafer.

24. The system according to claim 23 wherein the wafer holder includes a shaft, the system further comprising:
a motor coupled to the shaft to impart rotation to the wafer holder.

25. The system according to claim 23 wherein the first chamber includes an inlet and an outlet, the system further comprising:
a pump in fluid communication with the inlet and the outlet of the first chamber.

26. The system according to claim 25 wherein the inlet, the outlet, or both, are positioned in a manner which imparts circulation of the first electrolytic solution toward the wafer.

27. The system according to claim 23 further comprising:
a second chamber containing a second electrolytic solution comprising metal ions, wherein the wafer holder is adjustable between a first position where a wafer received therein is at least partially immersed in the first electrolytic solution and a second position where the wafer is at least partially immersed in the second electrolytic solution.

28. The system according to claim 23 further comprising:
a second chamber containing either a second electrolytic solution, deionized water, or alcohol, wherein the wafer holder is adjustable between a first position where a wafer received therein is at least partially immersed in the first electrolytic solution and a second position where the wafer is at least partially immersed in the second electrolytic solution, deionized water, or alcohol.

29. The system according to claim 23 further comprising:
a second chamber containing an electropolishing solution, wherein the wafer holder is adjustable between a first position where a wafer received therein is at least partially immersed in the first electrolytic solution and a second position where the wafer is at least partially immersed in the electropolishing solution.

30. The system according to claim 29 further comprising:
a cathode immersed at least partially in the electropolishing solution of the second chamber, wherein upon connection of the system to a power supply, an electrical current flows through the wafer, as anode, the electropolishing solution, and the cathode under conditions effective anodically to remove metal on a surface of the wafer in contact with the electropolishing solution.

31. The system according to claim 23 wherein the metal is copper, silver, gold, platinum, nickel, lead, palladium, tin, or alloys thereof.

32. The system according to claim 23 wherein the ligand is selected from the group consisting of halide ions, acetonitrile, cyanide ions, ammonia, thiosulfate, thiocyanate, sulfuric acid, nitric acid, EDTA, and combinations thereof.

33. The system according to claim 23 wherein the electrolytic solution comprises:
a copper source selected from the group consisting of copper salts, copper sulfate, copper nitrate, copper perchlorate, copper allyl sulfonate, copper halide, and combinations thereof; and
a ligand selected from the group consisting of halide ions, acetonitrile, cyanide ions, ammonia, thiosulfate, thiocyanate, sulfuric acid, nitric acid, EDTA, and combinations thereof.

34. The system according to claim 33 wherein the electrolytic solution comprises CuSO₄ and acetonitrile.

35. The system according to claim 33 wherein the electrolytic solution further comprises sulfuric acid.

36. The system according to claim 23 wherein the first electrolytic solution is substantially devoid of additives.

37. The system according to claim 23 wherein the anode is formed of a metal which is the same as the metal electrodeposited onto the wafer.

38. The system according to claim 37 further comprising:
a container comprising an agent which regenerates free ligand, the container being in fluid communication with the first chamber.

39. The system according to claim 38 wherein the agent which regenerates free ligand is an oxidant.

40. The system according to claim 23 wherein the anode is formed of an inert metal.

41. The system according to claim 40 further comprising:
a container comprising a metal ion source which also regulates the pH of the first electrolytic solution, the container being in fluid communication with the first chamber.

42. The system according to claim 41 wherein the metal is copper and the metal ion source is Cu(OH)₂, CuO, or CuCO₃.

43. A method of electroless deposition of metal onto a wafer comprising:
introducing a wafer, having a substantially flat surface and high-aspect ratio features each with an opening in the flat surface, at least partially into an electrolytic solution comprising metal ions, ligands, and metal ion-ligand complexes; and
exposing the wafer and the electrolytic solution to a metal sheet in sufficient proximity and electrically connected to the wafer, under conditions effective to reduce the metal ions, whereby deposition of metal occurs at a bottom of each of the features until the features are substantially super-filled.

44. The method according to claim 43 wherein said exposing induces a multiple step reduction of metal ions.

45. The method according to claim 43 further comprising after said exposing:
selectively removing metal from the flat surface between the openings of the features.

46. The method according to claim 43 wherein the metal is copper, silver, gold, platinum, nickel, lead, palladium, tin, or alloys thereof.

47. The method according to claim 43 wherein the ligand is selected from the group consisting of halide ions, acetonitrile, cyanide ions, ammonia, thiosulfate, thiocyanate, sulfuric acid, nitric acid, EDTA, and combinations thereof.

48. The method according to claim 43 wherein the electrolytic solution comprises:
a copper source selected from the group consisting of copper salts, copper sulfate, copper nitrate, copper perchlorate, copper alkyl sulfonate, copper halide, and combinations thereof; and
a ligand selected from the group consisting of halide ions, acetonitrile, cyanide ions, ammonia, thiosulfate, thiocyanate, sulfuric acid, nitric acid, EDTA, and combinations thereof.

49. The method according to claim 48 wherein the electrolytic solution comprises CuSO₄ and acetonitrile.

50. The method according to claim 48 wherein the electrolytic solution further comprises sulfinic acid.

51. The method according to claim 43 wherein the electrolytic solution is substantially devoid of additives.

52. The method according to claim 43 further comprising:
rotating the wafer during said exposing.

53. The method according to claim 43 further comprising:
circulating the electrolytic solution toward the wafer.

54. The method according to claim 43 further comprising:
repeating said introducing and exposing for different wafers; and
introducing into the electrolytic solution an agent which regenerates free ligand.

55. The method according to claim 54 wherein the agent which regenerates free ligand is an oxidant.

56. The method according to claim 43 further comprising:
repeating said introducing and exposing for different wafers; and
introducing into the electrolytic solution a metal ion source which also regulates the pH of the electrolytic solution.

57. The method according to claim 56 wherein the metal is copper and the metal ion source which also regulates the pH of the electrolytic solution is Cu(OH)₂, CuO, or CuCO₃.

58. The method according to claim 43 wherein the metal sheet is coated onto the substantially flat surface of the wafer.

59. A wafer comprising a metal interconnect which is prepared according to the process of claim 43.

60. A system comprising
a first chamber containing a first electrolytic solution comprising metal ions, ligands, and metal ion-ligand complexes;
a wafer holder adapted to receive a wafer such that the wafer is immersed at least partially in the first electrolytic solution of the first chamber; and
a metal sheet located in sufficient proximity and electrically connected to the wafer, upon introduction of the wafer into the wafer holder, which metal sheet induces reduction of the metal ions during deposition of metal onto the wafer.

61. The system according to claim 60 wherein the wafer holder includes a shaft, the system further comprising:
a motor coupled to the shaft to impart rotation to the wafer holder.

62. The system according to claim 60 wherein the first chamber includes an inlet and an outlet, the system further comprising:
a pump in fluid communication with the inlet and the outlet of the first chamber.

63. The system according to claim 62 wherein the inlet, the outlet, or both, are positioned in a manner which imparts circulation of the first electrolytic solution within the first chamber.

64. The system according to claim 60 further comprising:
a second chamber containing a second electrolytic solution comprising metal ions, wherein the wafer holder is adjustable between a first position where a wafer received therein is at least partially immersed in the first electrolytic solution and a second position where the wafer is at least partially immersed in the second electrolytic solution.

65. The system according to claim 60 further comprising:
a second chamber containing either a second electrolytic solution, deionized water, or alcohol, wherein the wafer holder is adjustable between a first position where a wafer received therein is at least partially immersed in the first electrolytic solution and a second position where the wafer is at least partially immersed in the second electrolytic solution, deionized water, or alcohol.

66. The system according to claim 60 further comprising:
a second chamber containing an electropolishing solution, wherein the wafer holder is adjustable between a first position where a wafer received therein is at least partially immersed in the first electrolytic solution and a second position where the wafer is at least partially immersed in the electropolishing solution.

67. The system according to claim 66 further comprising:
a cathode immersed at least partially in the electropolishing solution of the second chamber, wherein upon connection of the system to a power supply, an electrical current flows through the wafer, as anode, the electropolishing solution, and the cathode under conditions effective anodically to remove metal on a surface of the wafer in contact with the electropolishing solution.

68. The system according to claim 60 wherein the metal is copper, silver, gold, platinum, nickel, lead, palladium, tin, or alloys thereof.

69. The system according to claim 60 wherein the ligand is selected from the group consisting of halide ions, acetonitrile, cyanide ions, ammonia, thiosulfate, thiocyanate, sulfuric acid, nitric acid, EDTA, and combinations thereof.

70. The system according to claim 60 wherein the electrolytic solution comprises:
a copper source selected from the group consisting of copper salts, copper sulfate, copper nitrate, copper perchlorate, copper alkyl sulfonate, copper halide, and combinations thereof; and
a ligand selected from the group consisting of halide ions, acetonitrile, cyanide ions, ammonia, thiosulfate, thiocyanate, sulfuric acid, nitric acid, EDTA, and combinations thereof.

71. The system according to claim 70 wherein the electrolytic solution comprises CuSO₄ and acetonitrile.

72. The system according to claim 70 wherein the electrolytic solution further comprises sulfuric acid.

73. The system according to claim 60 wherein the first electrolytic solution is substantially devoid of additives.

74. The system according to claim 60 further comprising:
a container comprising an agent which regenerates free ligand, the container being in fluid communication with the first chamber.

75. The system according to claim 74 wherein the agent which regenerates free ligand is an oxidant.

76. The system according to claim 60 further comprising:
a container comprising a metal ion source which also regulates the pH of the first electrolytic solution, the container being in fluid communication with the first chamber.

77. The system according to claim 76 wherein the metal is copper and the metal ion source is Cu(OH)₂, CuO, or CuCO₃.

78. The system according to claim 60 wherein the wafer comprises a substantially flat surface and the metal sheet is coated onto the substantially flat surface of the wafer.
